(19) United States
(12) Patent Application Publication
(10) Pub. No.: US 2026/0182080 A1
(43) Pub. Date: Jun. 25, 2026

(54) STRING REPAIR DEVICE AND STRING REPAIR METHOD

(71) Applicant: HANWHA SOLUTIONS CORPORATION, Seoul (KR)

(72) Inventors: Han Jin LEE, Seoul (KR); Nam Gon KIM, Seoul (KR); Hyun Jae RYU, Seoul (KR)

(73) Assignee: HANWHA SOLUTIONS CORPORATION, Seoul (KR)

(21) Appl. No.: 19/129,058

(22) PCT Filed: May 3, 2024
(86) PCT No.: PCT/KR2024/006055

§ 371 Date: May 12, 2025

(30) Foreign Application Priority Data
May 25, 2023 (KR) 10-2023-0067619

(51) Int. Cl. H10F 77/30; H10F 19/90; H10F 71/00; H10F 77/00; H10F 77/20

(52) U.S. Cl. CPC H10F 77/311; H10F 19/904; H10F 19/906; H10F 71/1375; H10F 77/211; H10F 77/215; H10F 77/935

(57) ABSTRACT

A string repair device includes: a stage supporting a string including a plurality of solar cells including a plurality of printing areas and a plurality of wires connecting the plurality of solar cells; and a separating device configured to separate a plurality of wires attached to a plurality of printing areas of a defective solar cell among the plurality of solar cells from the defective solar cell, wherein the plurality of printing areas form a plurality of rows in a longitudinal direction, the separating device is present in an area that corresponds to the plurality of wires present in a plurality of printing areas of a first row among the plurality of printing areas of the defective solar cell, the separating device provides thermal energy of a first temperature or higher to the corresponding area, and the first temperature is a melting point of solder applied on the plurality of wires.

### TECHNICAL FIELD

The present disclosure relates to a string repair device and a string repair method.

### BACKGROUND ART

Solar cells, i.e., solar batteries, are formed by arranging diodes having p-n junctions on substrates. When solar cells are irradiated with solar radiation, excitons, which are electron-hole pairs, are generated, electrons move to the n-layer and holes move to the p-layer as the excitons are separated, and accordingly, a photoelectromotive force is generated at p-n junctions.

Tabbing is a process of forming a string, which is a single module of solar cells, by electrically connecting a plurality of solar cells using wires. A string extends in a straight line with a plurality of wires alternately arranged on front surfaces and rear surfaces of a plurality of solar cells. Wires arranged on a front surface of a single solar cell are alternately arranged by being arranged on a rear surface of an adjacent solar cell and then being arranged on a front surface of a subsequent solar cell.

However, conventionally, when some solar cells included in a string are defective, damaged, or not properly bonded to wires, there has been an inconvenience in that a person should directly remove the corresponding solar cells from the string, replace them with new solar cells, and bond the new solar cells. In particular, since a person should directly separate a wire attached to a defective solar cell in order to replace the defective solar cell with a new solar cell, there are problems that the entire process is prolonged and the worker may get injured.

### DISCLOSURE

### Technical Problem

Embodiments of the present disclosure are directed to providing a string repair device and a string repair method capable of automating a string repair process and effectively separating wires attached to a defective solar cell.

### Technical Solution

A string repair device includes: a stage supporting a string including a plurality of solar cells including a plurality of printing areas and a plurality of wires connecting the plurality of solar cells; and a separating device configured to separate a plurality of wires attached to a plurality of printing areas of a defective solar cell among the plurality of solar cells from the defective solar cell, wherein the plurality of printing areas form a plurality of rows in a longitudinal direction, the separating device is present in an area that corresponds to the plurality of wires present in a plurality of printing areas of a first row among the plurality of printing areas of the defective solar cell, the separating device provides thermal energy of a first temperature or higher to the corresponding area, and the first temperature is a melting point of solder applied on the plurality of wires.

The separating device may separate the plurality of wires attached to the plurality of printing areas of the first row among the plurality of printing areas of the defective solar cell from the defective solar cell.

The separating device may separate the plurality of wires from the defective solar cell throughout positions spaced a predetermined distance rearward from the plurality of printing areas of the first row.

The separating device may include a housing, a plurality of supply flow paths present inside the housing and connected to a gas supply source, a plurality of spray flow paths branched from lower ends of the plurality of supply flow paths, and a chamber present below the housing and in which the plurality of spray flow paths, a temperature sensor, and one or more auxiliary heaters are present, and the separating device may spray a high-temperature gas on the defective solar cell to separate the plurality of wires in the plurality of printing areas of the first row.

The one or more auxiliary heaters may heat the chamber and may maintain a temperature of the chamber below a temperature of a gas discharged from the plurality of supply flow paths.

The chamber may include a first inner space communicating with each of the plurality of supply flow paths and the plurality of spray flow paths and a pair of second inner spaces present on both sides of the first inner space, the temperature sensor may be present in the first inner space, and the one or more auxiliary heaters may be present in the pair of second inner spaces.

The chamber may include, in a bottom surface thereof, a plurality of spray grooves having a length greater than a diameter of the plurality of spray flow paths and extending to be inclined to both sides from lower ends of the plurality of spray flow paths.

A string repair method includes placing a string including a plurality of solar cells including a plurality of printing areas and a plurality of wires connecting the plurality of solar cells on a stage, separating a plurality of wires attached to a plurality of printing areas of a defective solar cell among the plurality of solar cells from the defective solar cell, and cutting the separated plurality of wires, wherein the plurality of printing areas form a plurality of rows in a longitudinal direction, the separating of the plurality of wires from the defective solar cell includes providing thermal energy of a first temperature or higher to an area that corresponds to the plurality of wires present in a plurality of printing areas of a first row among the plurality of printing areas of the defective solar cell, and the first temperature is a melting point of solder applied on the plurality of wires.

The separating may include separating the plurality of wires attached to the plurality of printing areas of the first row among the plurality of printing areas of the defective solar cell from the defective solar cell.

The separating of the plurality of wires from the defective solar cell may include separating the plurality of wires from the defective solar cell throughout positions spaced a predetermined distance rearward from the plurality of printing areas of the first row.

### Advantageous Effects

A string repair device and a string repair method according to embodiments of the present disclosure can automate a string repair process and can effectively separate a plurality of wires attached to a defective solar cell using a separating device.

### DESCRIPTION OF DRAWINGS

FIG. 1 schematically illustrates a string manufacturing system including a string repair device.

FIGS. 2A to 2L illustrate operations of the string repair device.

FIG. 3 illustrates one of the operations of the string repair device.

FIGS. 4 and 5 illustrate cross-sections of a separating device.

FIG. 6 illustrates a bottom surface of the separating device.

### BEST MODE OF THE INVENTION

A string repair device includes: a stage supporting a string including a plurality of solar cells including a plurality of printing areas and a plurality of wires connecting the plurality of solar cells; and a separating device configured to separate a plurality of wires attached to a plurality of printing areas of a defective solar cell among the plurality of solar cells from the defective solar cell, wherein the plurality of printing areas form a plurality of rows in a longitudinal direction, the separating device is present in an area that corresponds to the plurality of wires present in a plurality of printing areas of a first row among the plurality of printing areas of the defective solar cell, the separating device provides thermal energy of a first temperature or higher to the corresponding area, and the first temperature is a melting point of solder applied on the plurality of wires.

### Modes of the Invention

Embodiments of the present disclosure and methods of accomplishing the same may be understood more readily with reference to the detailed description of the embodiments and the accompanying drawings. Hereinafter, the embodiments will be described in more detail with reference to the accompanying drawings. The described embodiments, however, may have various modifications and may be embodied in various different forms, and should not be construed as being limited to only the illustrated embodiments herein. In addition, different features of various embodiments of the present disclosure may be combined, may be combined with each other partially or entirely, or may be technically linked and driven in various ways. Different embodiments may be embodied independently from each other or may be embodied together in association with each other. The embodiments described herein are provided as examples to make the present disclosure thorough and complete and to fully convey the idea of the present disclosure to those of ordinary skill in the art, and it should be understood that the present disclosure covers all modifications, equivalents, and replacements within the idea and technical scope of the present disclosure. Accordingly, processes, components, and techniques that are not necessary to those of ordinary skill in the art for a complete understanding of the aspects of the present disclosure may not be described.

Unless otherwise noted, like reference numerals, characters, or combinations thereof denote like components throughout the attached drawings and the written description, and thus descriptions thereof will not be repeated. Further, parts that are irrelevant to the description of the embodiments may be omitted to make the description clear.

In the drawings, the relative sizes of components, layers, and regions may be exaggerated for clarity. Additionally, the use of cross-hatching and/or shading in the accompanying drawings is generally provided to clarify boundaries between adjacent components. As such, neither the presence nor the absence of cross-hatching or shading conveys or indicates any preference or requirement for particular materials, material properties, dimensions, proportions, commonalities between illustrated components, and/or any other characteristic, attribute, property, etc., of the components, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

The regions illustrated in the drawings are schematic in nature and their shapes are not intended to illustrate the actual shape of a region of a device nor intended to be limiting. Additionally, as those skilled in the art would realize, the described embodiments may be modified in various different ways, all without departing from the spirit or scope of the present disclosure.

In the specification, numerous specific details are set forth to provide a thorough understanding of various embodiments. However, various embodiments may be practiced without these specific details or with one or more of the details. In other instances, well-known structures and devices are shown in block diagram form in order to avoid unnecessarily obscuring various embodiments.

Spatially relative terms, such as “beneath,” “above,” “below,” and “on,” may be used herein for ease of explanation to describe one component or feature's relationship to another component(s) or feature(s) as illustrated in the figures. The spatially relative terms are intended to encompass different orientations of the device in use or in operation, in addition to the orientation depicted in the figures. For example, if the device in the figures is turned over, components described as “below” or “beneath” other components or features would then be oriented “above” the other components or features. Thus, the example terms “below” and “beneath” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part.

In addition, the phrase “in a plan view” means viewing an object from the top, and the phrase “in a schematic cross-sectional view” means viewing a schematic cross-section formed by vertically cutting an object. The phrase “viewed from a side” means that a first object may be present above, below, or beside a second object, and vice versa. In addition, the term “overlap” or “overlapped” may include layer, stack, face or facing, extending over, covering, or partly covering or any other suitable term as would be appreciated and understood by those of ordinary skill in the art. The phrase “not overlap” may include meanings such as “being apart from” or “being spaced from” or any other suitable equivalents as would be appreciated and understood by those of ordinary skill in the art. The terms “face” and “facing” may mean that a first object may directly or indirectly oppose a second object. In the case where a third object is present between the first object and the second object, the first object and the second object may be understood as being indirectly opposed to each other, although still facing each other.

When an element, layer, region, or component is referred to as being “formed on,” “connected to,” or “coupled to” another element, layer, region, or component, the other element, layer, region, or component may be directly formed on the element, layer, region, or component, or the element, layer, region, or component may be formed on the other element, layer, region, or component or may be indirectly formed on, connected to, or coupled to the other element, layer, region, or component. In addition, “formed on,” “connected to,” or “coupled to” may collectively mean a direct or indirect coupling or connection and an integral or non-integral coupling or connection of elements, layers, regions, or components for one or more elements, layers, regions, or components to be present. For example, when an element, layer, region, or component is referred to as being “electrically connected” or “electrically coupled” to another element, layer, region, or component, the element, layer, region, or component can be directly electrically connected or coupled to the other element, layer, region, or component or other elements, layers, regions, or components may be present. However, “directly connected” or “directly coupled” refers to one component directly connecting or coupling another component, or being on another component, without an intermediate component. In addition, if a portion of a layer, film, region, guide plate, or the like is formed on another portion, a formation direction is not limited to an upper direction, and the portion may be formed on a side surface of or under the other portion. In contrast, if a portion of a layer, film, region, guide plate, or the like is formed “under” another portion, the portion may be “just underneath” the other portion, or an intervening portion may be present between the portion and the other portion. Meanwhile, other expressions describing relationships between components such as “between,” “immediately between” or “adjacent to” and “directly adjacent to” may be construed similarly. In addition, if an element or layer is referred to as being “between” two elements or layers, this may be the only element between the two elements or layers, or another element may be present therebetween.

For the purposes of this specification, the expressions such as “at least one” or “any one” do not limit the order of individual elements. For example, “at least one of X, Y, and Z,” “at least one of X, Y, or Z,” and “at least one selected from the group consisting of X, Y, and Z” may include any combination of two or more of X alone, Y alone, Z alone, and two or more of X, Y, and Z. Similarly, the expressions such as “at least one of A and B” and “at least one of A or B” may include A, B, or A and B. In this specification, the term “and/or” generally includes all combinations of one or more related list items. For example, expressions such as “A and/or B” may include A, B, or A and B.

The terms “first,” “second,” “third,” etc. may be used herein to describe various elements, components, regions, layers, and/or cross-sections, but these elements, components, regions, layers, and/or cross-sections are not limited by these terms. These terms are used to distinguish one element, component, region, layer, or cross-section from another element, component, region, layer, or cross-section. Therefore, a first element, component, region, layer, or cross-section described below may be referred to as a second element, component, region, layer, or cross-section without departing from the spirit and scope of the present invention. Describing an element as a “first” element may not require or imply the presence of a second element or another element. The terms “first,” “second,” etc. may be used herein to distinguish between different categories or sets of elements. In order to express clearly, the terms “first,” “second,” etc. may refer to a “first category (or a first set),” a “second category (or a second set),” and the like, respectively.

The terms used herein are used only to describe particular embodiments and are not intended to limit the present invention. As used herein, a singular expression is intended to include a plural expression, and the plural expression is also intended to include a singular form unless the context clearly indicates otherwise. The terms “comprise,” “include,” and “have” mean specifying the presence of specified features, integers, and steps if used herein. These expressions do not preclude the presence or addition of one or more other functions, steps, operations, components, and/or groups thereof.

If one or more embodiments may be embodied differently, a particular process order may be performed differently from the order described. For example, two processes described in succession may be performed substantially simultaneously or in the opposite order to the order described.

The terms “substantially,” “about,” “approximately,” and similar terms are used not as terms of degree but as terms of approximation and indicate that the terms satisfy the range of intrinsic deviations of measured or calculated values (e.g., the range of deviations due to limitations of a measurement system). For example, “about” may mean within one or more standard deviations or within ±30%, 20%, 10%, and 5% of stated values.

Unless otherwise defined, all terms used herein, including technical or scientific terms, have the same meaning as those generally understood by one of ordinary skill in the art to which the present invention belongs. Terms, such as those defined in commonly used dictionaries, should be interpreted as having a meaning that is consistent with their meaning in the context of the relevant art and/or the present specification and will not be interpreted in an idealized or overly formal sense unless expressly so defined herein.

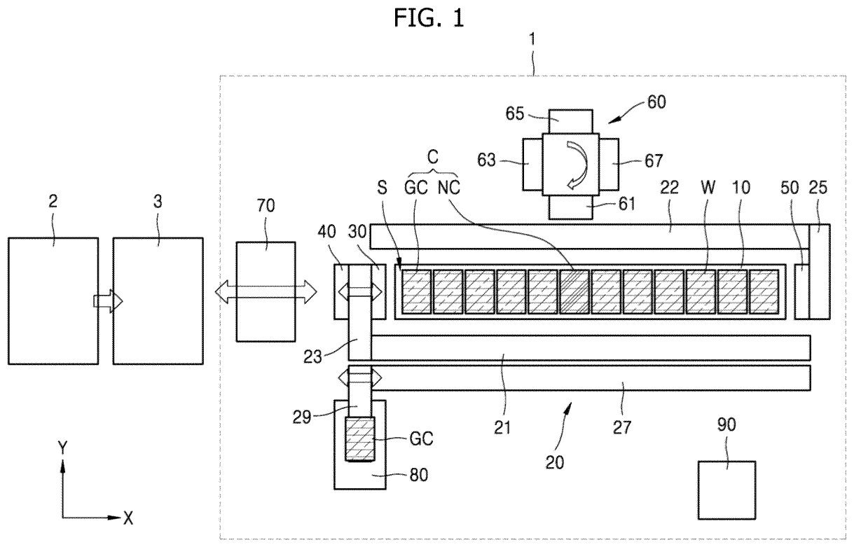

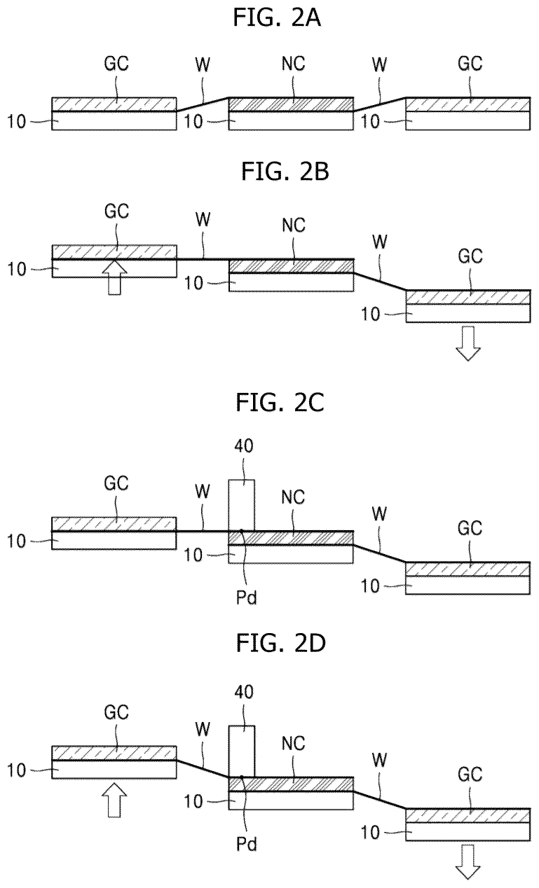

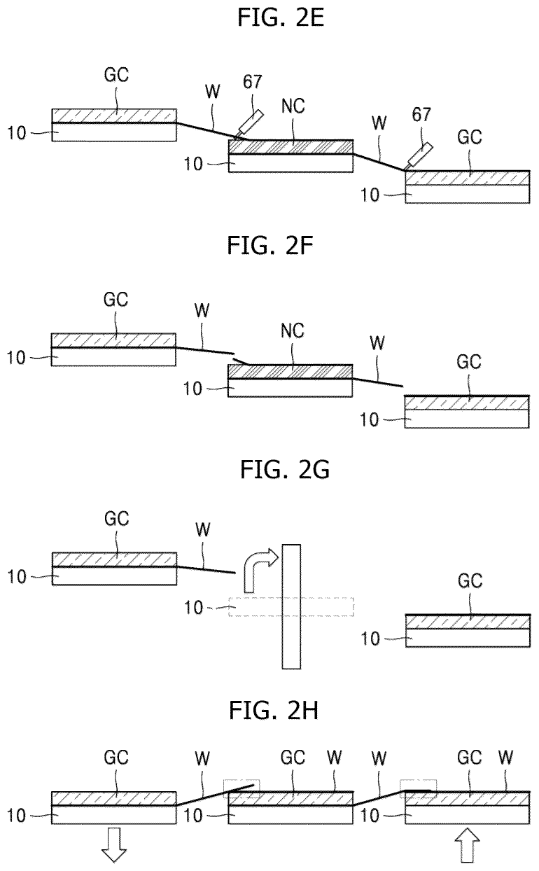

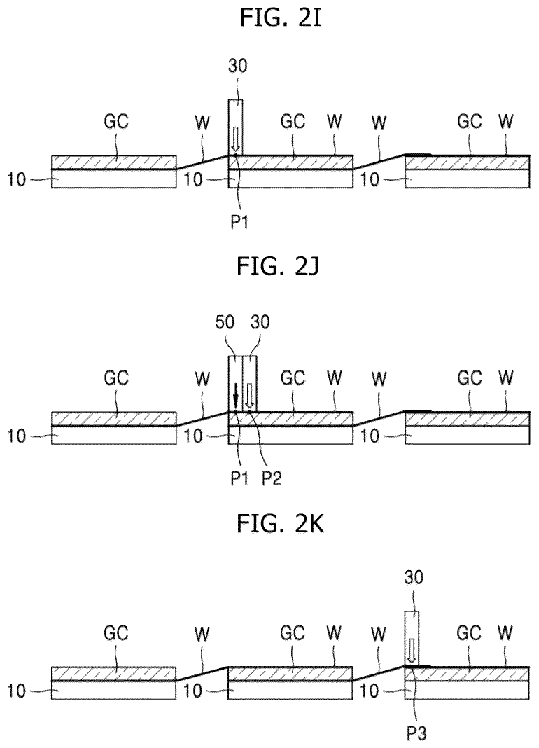

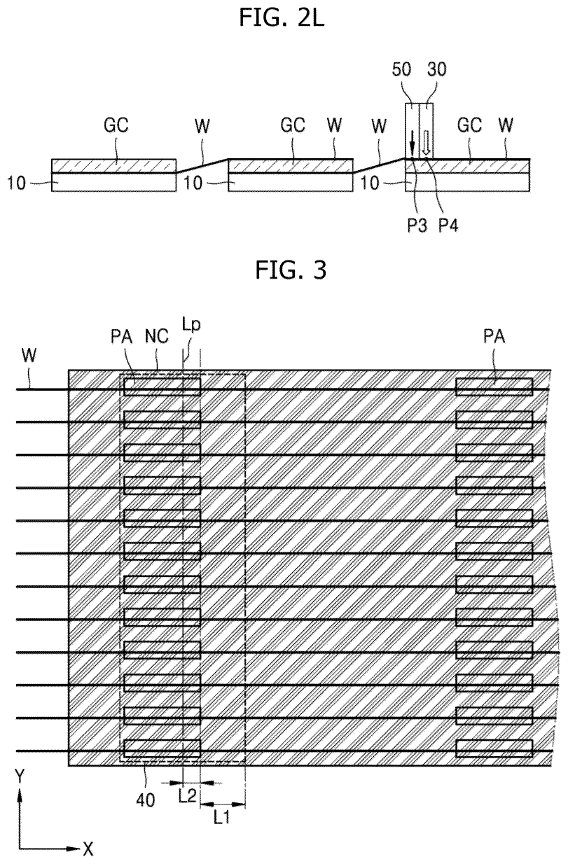

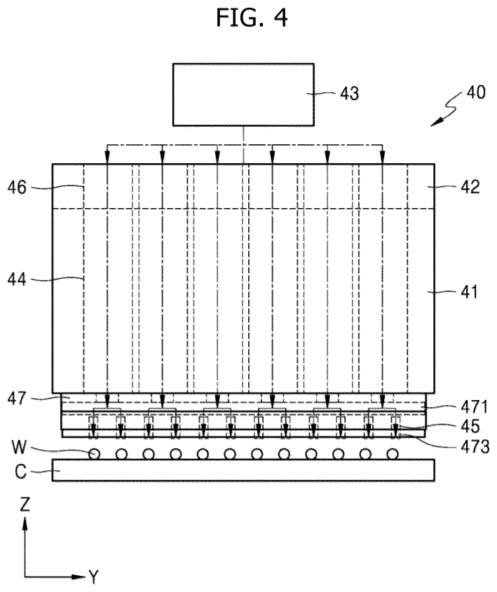

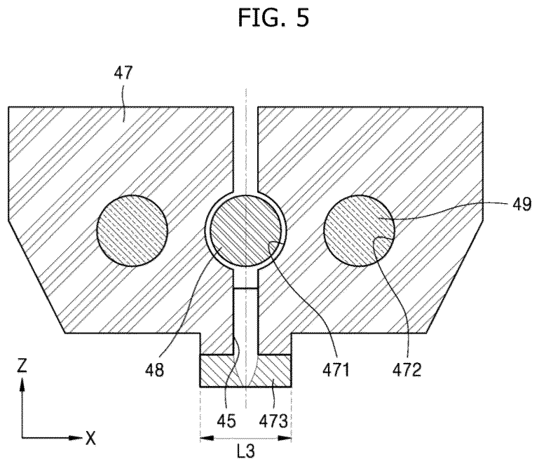

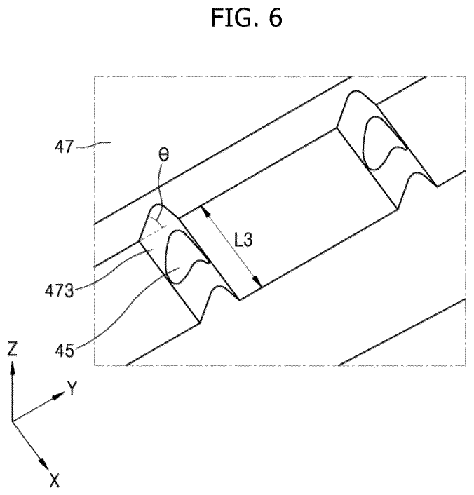

FIG. 1 schematically illustrates a string manufacturing system including a string repair device 1, FIGS. 2A to 2L illustrate operations of the string repair device 1, and FIG. 3 illustrates one of the operations of the string repair device 1 in a state in which a separating device 40 is placed on a plurality of wires W of a defective solar cell NC. FIGS. 4 and 5 illustrate cross-sections of the separating device 40, and FIG. 6 illustrates a bottom surface of the separating device 40.

Referring to FIG. 1, the string repair device 1 may be included in the string manufacturing system together with a tabbing device 2 and an inspecting device 3. The tabbing device 2 may produce a string S by connecting solar cells C and wires W. The string S may include a plurality of solar cells C and a plurality of wires W connecting the plurality of solar cells C. The plurality of solar cells C may be arranged in a first direction (for example, the X-axis direction of FIG. 1), and the plurality of wires W may be attached alternately to one surface and another surface of each solar cell C and electrically connect the plurality of solar cells C. For example, as illustrated in FIG. 2A, a wire W attached to a lower surface of any one solar cell C may be attached to an upper surface of an adjacent solar cell C. Also, a wire W attached to an upper surface of any one solar cell C may be attached to a lower surface of an adjacent solar cell C. For convenience of description, FIGS. 2A to 2L illustrate that only one wire W is attached to solar cells C located at both sides of a solar cell C that is to be replaced or has been replaced, but the corresponding solar cells C may also have wires W additionally attached to an upper surface and a lower surface thereof as described above.

The number of solar cells C and wires W included in a single string S may be appropriately selected according to specifications of the string S. For example, twelve solar cells C may be arranged consecutively in a single string S, and six or twelve wires W may be attached to a single solar cell C in a width direction of the solar cell C (for example, a second direction or the Y-axis direction of FIG. 3). Although six wires W are shown in FIG. 1 for convenience of description, twelve wires W may be attached to each of a plurality of solar cells C in the width direction of the solar cells C as shown in FIG. 3.

Each solar cell C may include a plurality of printing areas PA. The printing areas PA may be areas where a plurality of wires W are attached to a solar cell C, and for example, as illustrated in FIG. 3, a plurality of printing areas PA may be formed on a single solar cell C in the longitudinal direction and width direction thereof. The printing areas PA may include a conductive material. The wires W may be electrically connected to the solar cell C through the printing areas PA. Each wire W may be attached to the plurality of printing areas PA formed in the longitudinal direction of a single solar cell C (for example, the first direction or the X-axis direction FIG. 3) through pre-applied solder. Also, a width of the printing area PA may be greater than a diameter of the wire W. Printing areas PA equal in number to the plurality of wires W may be formed on a single solar cell C in the width direction thereof (for example, the second direction or the Y-axis direction of FIG. 3). For example, the plurality of printing areas PA may form a plurality of rows in the longitudinal direction. A single row of printing areas PA may include twelve printing areas PA arranged on a single solar cell C in the width direction thereof. Hereinafter, for convenience of description, “first printing area PA row” may refer to a row of printing areas PA located at the front in the longitudinal direction, that is, for example, located first on the left side of FIGS. 2A to 2L, among the plurality of rows of printing areas PA formed on a single solar cell C.

The inspecting device 3 may inspect the string S produced by the tabbing device 2 for defects or foreign substances. The inspecting device 3 may capture overall images of a front surface and a rear surface of the string S using a vision camera and may inspect whether solar cells C are damaged, whether connection between wires W and the solar cells C is good, whether there are foreign substances on the solar cells C, etc. If inspection results are normal, the string S may be conveyed to a subsequent process without a separate repair process. If inspection results show that there is a defect, the string S may be conveyed to the string repair device 1. In addition, the inspecting device 3 may also inspect the repaired string S to check whether the repair was done properly.

The string repair device 1 may repair and replace a string S determined to be defective by the inspecting device 3. For example, the string repair device 1 may replace a solar cell C, which is determined to be a defective solar cell NC by the inspecting device 3 among the plurality of solar cells C included in the string S, with a good solar cell GC.

The string repair device 1 may include a stage 10, a movement guide 20, the aligning device 30, a separating device 40, the bonding device 50, a robot arm 60, a transporting device 70, a magazine 80, and a controller 90.

The stage 10 is located side by side with one side of the string repair device 1 in the first direction (for example, the X-axis direction of FIG. 1) and supports the string S. The stage 10 may include a mechanical device (for example, a gripper or a clamping means) for supporting the string S or may support the string S by adsorption. When the string S is determined to be defective by the inspecting device 3, the transporting device 70 may place the string S on an upper surface of the stage 10.

The stage 10 may be divided into three parts. A defective solar cell NC to be replaced may be located on a stage 10 located at a central portion, and the remaining good solar cells GC may be located on the stages 10 remaining at both sides. Alternatively, if a defective solar cell NC included in a string S is a solar cell C located at the very front or very rear in the first direction, the defective solar cell NC may be seated on any one stage 10, the remaining good solar cell GC may be seated on another stage 10, and the remaining stage 10 may be unoccupied.

The stage 10 may move upward and downward in a height direction to adjust the height of the defective solar cell NC to match the heights of two good solar cells GC adjacent thereto. For example, as illustrated in FIG. 2A, the plurality of solar cells C included in the string S may be seated on the stage 10, and here, the three parts that the stage 10 includes may all be located at the same height. Then, as illustrated in FIG. 2B, the two stages 10 adjacent to the front and rear (e.g., the left side and right side of FIG. 2B) of the stage 10 on which the defective solar cell NC is located may move upward and downward, and height differences may be formed between the defective solar cell NC and the two good solar cells GC adjacent thereto. In this way, the heights of the stages 10 may be adjusted to make it easy to cut the plurality of wires W connecting the defective solar cell NC and the good solar cells GC adjacent thereto. The heights of the stages 10 may be adjusted by the stages 10 themselves moving in the height direction or tilting. The wires W may be easily cut due to the height differences formed between the stages 10.

The stage 10 may further move upward after or during the separating operation of the separating device 40. For example, as illustrated in FIG. 2C, in a state in which the stages 10 located at the front and rear of the defective solar cell NC have moved upward and downward, respectively, the separating device 40 may perform an operation of separating the plurality of wires W attached to the defective solar cell NC. Then, as illustrated in FIG. 2D, the stage 10 located at the front of the defective solar cell NC may further move upward and may pull the wire W attached to an upper surface of the defective solar cell NC upward. Accordingly, a force pulling the wire W upward is added to the separating operation of the separating device 40, and the wire W attached to the upper surface of the defective solar cell NC may be separated more easily. The stage 10 located at the rear of the defective solar cell NC may further move downward and may pull the wire W attached to a lower surface of the defective solar cell NC downward.

The further upward movement and downward movement of the stages 10 may be performed after the separating operation of the separating device 40 after the separating device 40 deviates from the wires W or may be performed simultaneously with the separating operation of the separating device 40 while the separating device 40 is in contact with the wires W.

The stages 10 may also be movable in the first direction (for example, the X-axis direction of FIG. 1). The stages 10 located at both sides of the stage 10 on which the defective solar cell NC is seated may move forward or backward in the longitudinal direction. Accordingly, distances between the defective solar cell NC and the good solar cells GC adjacent thereto may be adjusted, and the tasks of separating, cutting, and aligning the wires W may be more easily performed.

The stage 10 on which the defective solar cell NC is seated may be rotatable. For example, as illustrated in FIG. 2G, the stage 10 may rotate clockwise or counterclockwise to discharge the defective solar cell NC after the wires W are cut. Accordingly, the defective solar cell NC seated on the stage 10 may be discharged from the stage 10, the stage 10 may rotate back to its original position, and then a new good solar cell GC may be seated on the stage 10.

The movement guide 20 may move the aligning device 30, the separating device 40, and the bonding device 50 along designated paths according to each string repair process. In addition, after the defective solar cell NC is removed from the string S, the movement guide 20 may move a good solar cell GC loaded in the magazine 80 to the position where the defective solar cell NC was present.

The movement guide 20 may include a first horizontal guide 21, a second horizontal guide 22, a first moving head 23, a second moving head 25, a third horizontal guide 27, and a third moving head 29.

The first horizontal guide 21 may extend in the first direction (for example, the X-axis direction of FIG. 1) side by side with the stage 10 and may be spaced from the stage 10. The first moving head 23 may be connected to the first horizontal guide 21, and the first moving head 23 may, while moving along the first horizontal guide 21, perform a task on the string S placed on the stage 10.

The second horizontal guide 22 may be located on the opposite side of the first horizontal guide 21 based on the stage 10 and may be side by side with the stage 10. The second moving head 25 may be connected to the second horizontal guide 22, and the second moving head 25 may, while moving along the second horizontal guide 22, perform a task on the string S placed on the stage 10.

The aligning device 30 and the separating device 40 may be connected to the first moving head 23. For example, as illustrated in FIG. 1, the aligning device 30 may be connected to one side of the first moving head 23, and the separating device 40 may be connected to the other side, which is the opposite side of the aligning device 30. Therefore, when the first moving head 23 moves, the aligning device 30 and the separating device 40 connected to the first moving head 23 may move together. The first moving head 23 may move so that the separating device 40 is located on a wire w to be separated of the defective solar cell NC among the plurality of solar cells C included in the string S. In addition, the first moving head 23 may move so that the aligning device 30 is located on a wire W cut by a cutter 67. In addition, the first moving head 23 may move in the height direction and may simultaneously or separately lift or lower the aligning device 30 and the separating device 40 mounted thereon.

Alternatively, the first moving head 23 may include a plurality of first moving heads 23, and the aligning device 30 and the separating device 40 may be connected to each first moving head 23. Alternatively, the first moving head 23 may include a plurality of first moving heads 23, and a single aligning device 30 or a single separating device 40 may be connected to each first moving head 23.

The bonding device 50 may be connected to the second moving head 25. The second moving head 25 may move to a wire W aligned by the aligning device 30 and may allow the bonding device 50 to be placed on the cut wire W and a wire W attached to a new good solar cell GC. In addition, the second moving head 25 may move in the height direction and may lift or lower the mounted bonding device 50. Alternatively, the second moving head 25 may include a plurality of second moving heads 25.

The third horizontal guide 27 may extend in the first direction side by side with the stage 10 and may be adjacent to the first horizontal guide 21. Alternatively, the third horizontal guide 27 may be connected to a side of the second horizontal guide 22. The third moving head 29 is connected to the third horizontal guide 27, and while moving along the third horizontal guide 27, the third moving head 29 may support the good solar cell GC loaded in the magazine 80 and may move the good solar cell GC to the position where the defective solar cell NC was present.

The aligning device 30 may, while moving along the movement guide 20, align the wires W of the string S placed on the stage 10. The aligning device 30 may, once the defective solar cell NC is discharged from the stage 10 and a good solar cell GC is placed on the stage 10, align wires W attached to the good solar cell GC and wires W attached to two other solar cells GC adjacent thereto.

The aligning device 30 may maintain a plurality of wires W attached to the new solar cell GC and a plurality of wires W of the two solar cells GC adjacent to the new solar cell GC in a plurality of printing areas PA. In addition, the aligning device 30 may support the wires W at a position adjacent to the bonding device 50 when the bonding device 50 bonds the wires W. The aligning device 30 may be connected to the first moving head 23 connected to the first horizontal guide 21.

The aligning device 30 may place the plurality of wires W connected to the solar cell GC adjacent to the new solar cell GC in a first printing area PA row. For example, the aligning device 30 may align the plurality of wires W of the solar cell GC adjacent to the new solar cell GC so that the plurality of wires W are placed in the first printing area PA row in the longitudinal direction of the new solar cell GC (for example, the first direction). In addition, the aligning device 30 may align the plurality of wires W attached to the new solar cell GC so that the plurality of wires W are placed in the first printing area PA row of the solar cell GC adjacent to the other side of the new solar cell GC.

The aligning device 30 may primarily move downward to a position spaced a predetermined height from an upper surface of the solar cell C to align the plurality of wires W downward and may secondarily move downward so that a lower end comes into contact with the upper surface of the solar cell C. Then, the aligning device 30 may align the plurality of wires W in a width direction so that the plurality of wires W are placed in the first printing area PA row in the longitudinal direction among the plurality of printing areas PA.

The aligning device 30 may primarily move downward from a first position P1 corresponding to the first printing area PA row and then may move a predetermined distance rearward. Then, the aligning device 30 may secondarily move downward from a second position P2, press the plurality of wires W to the upper surface of the solar cell C, and then align the plurality of wires W in the width direction.

For example, as illustrated in FIG. 21, the aligning device 30 may primarily move downward from the first position P1 corresponding to the first printing area PA row of the new solar cell GC and may align the plurality of wires W downward. Next, as illustrated in FIG. 2J, the aligning device 30 may secondarily move downward from the second position P2 that is reached by moving a predetermined distance rearward from the first position P1 and spaced rearward from the first printing area PA row, may press the plurality of wires W to an upper surface of the solar cell C, and then may align the plurality of wires W in the width direction. Then, as illustrated in FIG. 2K, the aligning device 30 may primarily move downward from a third position P3 corresponding to the first printing area PA row of the good solar cell GC at the rear of the new solar cell GC and may align the plurality of wires W downward. Next, as illustrated in FIG. 2L, the aligning device 30 may secondarily move downward from a fourth position P4 that is reached by moving a predetermined distance rearward from the third position P3 and spaced rearward from the first printing area PA row, may press the plurality of wires W to an upper surface of the solar cell C, and then may align the plurality of wires W in the width direction.

The separating device 40 may separate a wire W attached to a solar cell C. The separating device 40 may be mounted on the first moving head 23 and may be used in separating a plurality of wires W attached to a defective solar cell NC. For example, as illustrated in FIG. 2B, in a state in which the stages 10 supporting good solar cells GC adjacent to a defective solar cell NC have moved upward and downward, based on the defective solar cell NC, the separating device 40 may move to an upper portion of the defective solar cell NC. Here, the separating device 40 may be adjacent to an end of the defective solar cell NC (for example, a left end thereof in FIG. 2B). The separating device 40 may be located to correspond to a wire W attached to a printing area PA closest to an end of the defective solar cell NC, that is, the first printing area PA row.

The separating device 40 may only be used in separating a plurality of wires W attached to an upper surface of a defective solar cell NC and may not be used in separating a plurality of wires W attached to an upper surface of a good solar cell GC located at the rear of the defective solar cell NC. That is, in order to replace the defective solar cell NC with a good solar cell GC, the plurality of wires W attached to the upper surface of the defective solar cell NC and the plurality of wires W attached to the upper surface of the good solar cell GC located at the rear of the defective solar cell NC should all be cut. Here, since the plurality of wires W attached to the upper surface of the defective solar cell NC should be attached to printing areas PA of the new good solar cell GC, the plurality of wires W need to be cut at sufficient lengths. On the other hand, since the plurality of wires W attached to the upper surface of the good solar cell GC located at the rear of the defective solar cell NC are discharged together with the defective solar cell NC, the plurality of wires W may be cut short to have ends thereof adjacent to ends of the stage 10. Accordingly, in order to reduce the time taken for the entire string repair process, the separating device 40 may only be used in separating the plurality of wires W attached to the upper surface of the defective solar cell NC.

The separating device 40 may come into contact with a wire W at a separation position Pd. For example, as illustrated in FIGS. 2C and 2D, the separation position Pd may be located within the first printing area PA row closest to the stage 10 located at the front among the plurality of printing areas PA of the defective solar cell NC or may be located adjacent to the first printing area PA row. Here, the separation position Pd is a position where the center of the separating device 40 comes into contact with a wire W in the second direction (for example, the width direction of the solar cells C or the Y-axis direction of FIG. 3) that intersects with the first direction.

For example, as illustrated in FIG. 3, the separating device 40 may include the entire first printing area PA row. A line Lp in FIG. 3 is a line where the center of the separating device 40 is located and represents a virtual line extending through a plurality of separation positions Pd. Also, dotted lines shown with the reference numeral 40 in FIG. 3 may represent the position of the separating device 40 itself or an area in which separation is performed by the separating device 40. Accordingly, the wires W may be separated by the separating device 40 to areas longer toward the rear than the first printing area PA row, and the wires W may be cut at sufficient lengths by the robot arm 60 afterwards. Then, the cut wires W may be stably attached to the printing areas PA of the new solar cell GC.

Once the plurality of wires W are separated from the defective solar cell NC in the plurality of printing areas PA of the first row by the separating device 40, due to the height differences between the stages 10, the plurality of wires W may be naturally separated from the defective solar cell NC also in areas located in front of the plurality of printing areas PA of the first row. Alternatively, the separating device 40 may separate the plurality of wires W from the defective solar cell NC throughout areas ranging from a front end of the defective solar cell NC to positions spaced a predetermined distance (for example, L1 in FIG. 3) rearward from the plurality of printing areas PA of the first row.

The separating device 40 may separate the plurality of wires W from the defective solar cell NC throughout positions spaced a predetermined distance rearward from the plurality of printing areas PA of the first row. Accordingly, as illustrated in FIGS. 2E and 2F, the plurality of wires W attached to the good solar cell GC located at the front of the defective solar cell NC may be cut to extend to above the defective solar cell NC.

A rear end of the separating device 40 or a rear end of an area in which the plurality of wires W are separated by the separating device 40 may be spaced the distance L1 rearward from a rear end of the first printing area PA row. Accordingly, the wires W are separated from the upper surface of the defective solar cell NC not only in sections attached to the first printing area PA row but also in sections placed behind the first printing area PA row, and the wires W can be cut at sufficient lengths. The center line Lp of the separating device 40 may be spaced a distance L2 forward from the rear end of the first printing area PA row to be located within the first printing area PA row. Accordingly, the first printing area PA row may be entirely included in the area in which the plurality of wires W are separated by the separating device 40, and the plurality of wires W may be more reliably separated in the first printing area PA row. The distance L2 may be shorter than half the length of the printing area PA.

The separating device 40 may be present in an area corresponding to the plurality of wires W present in the plurality of printing areas PA of the first row among the plurality of printing areas PA of the defective solar cell NC. Then, the separating device 40 may provide thermal energy of a first temperature or higher to the corresponding area, and here, the first temperature may be a melting point of solder applied on the plurality of wires W. That is, the separating device 40 may heat the plurality of wires W at positions corresponding to the plurality of printing areas PA of the first row, and at this time, the separating device 40 may heat the plurality of wires W to a temperature higher than or equal to the melting point of the solder applied on the plurality of wires W so that the solder melts.

The separating device 40 may be a hot air blower. The separating device 40 may separate a plurality of wires W from a defective solar cell NC by spraying high-temperature air or a gas satisfying a predetermined atmosphere onto the plurality of wires W to melt solder between the plurality of wires W and the defective solar cell NC

The separating device 40 may be equal in number to a plurality of wires W attached to a single solar cell C. The separating devices 40 may simultaneously spray hot air to twelve wires W through twelve outlets. Alternatively, the separating device 40 may be fewer in number than a plurality of wires W attached to a single solar cell C. The separating devices 40 may spray hot air to six wires W through six outlets, move, and then spray hot air to the remaining six wires W.

The separating device 40 may include a housing 41, an upper case 42, a gas supply source 43, a supply flow path 44, a spray flow path 45, a control valve 46, a chamber 47, a temperature sensor 48, and an auxiliary heater 49.

The housing 41 may support and contain other components of the separating device 40. For example, as illustrated in FIG. 4, a plurality of supply flow paths 44 may be present inside the housing 41. The upper case 42 may be present on the housing 41, and a plurality of control valves 46 may be present inside the upper case 42 to correspond to the plurality of supply flow paths 44. The plurality of control valves 46 may be individually connected to the gas supply source 43, and the amount of gas supplied to each supply flow path 44, whether to supply a gas thereto, etc., may be controlled by the controller 90. The gas supply source 43 may be connected to the separating device 40 and may supply high-temperature air or a gas having a predetermined atmosphere to the plurality of control valves 46. The pressure of the gas supplied from the gas supply source 43 may be controlled by the plurality of control valves 46. For example, the temperature of the gas supplied from the gas supply source 43 may range from 400° C. to 600° C., and the pressure of the gas may range from 0.1 MPa to 0.5 MPa.

The supply flow path 44 is a hollow cylindrical flow path, and a plurality of supply flow paths 44 may be present inside the housing 41. Upper ends of the supply flow paths 44 may each be connected to one of the plurality of control valves 46, and lower ends of the supply flow paths 44 may each be connected to one of a plurality of spray flow paths 45. A high-temperature gas supplied from the gas supply source 43 may be supplied to the plurality of supply flow paths 44 via the plurality of control valves 46 and may be sprayed to each of the plurality of wires W through the plurality of spray flow paths 45.

The number of supply flow paths 44 may be less than the number of wires W. For example, as illustrated in FIG. 4, one supply flow path 44 may correspond to two wires W. Six supply flow paths 44 may be present.

The spray flow path 45 may be branched from the lower end of the supply flow path 44 and may head toward the wire W. Two spray flow paths 45 may be branched from the lower end of one supply flow path 44. For example, as illustrated in FIG. 4, two spray flow paths 45 branched from one supply flow path 44 may each be spaced from a central axis of the supply flow path 44. Also, the spray flow paths 45 may be equal in number to the wires W, and when the separating device 40 is located at the separation position Pd, each spray flow path 45 may be present on one of the wires W. The plurality of spray flow paths 45 may be formed inside the chamber 47. For example, as illustrated in FIG. 4, the plurality of spray flow paths 45 may communicate with a first inner space 471.

The plurality of control valves 46 may be present inside the upper case 42 to correspond to the plurality of supply flow paths 44. The control valves 46 may be controlled by the controller 90 and may individually control a gas supplied from the gas supply source 43 to each supply flow path 44. An opening degree of the control valves 46 may be controlled to control the flow rate and pressure of the gas supplied to each supply flow path 44.

As illustrated in FIG. 4, the chamber 47 may be present at a lower end of the housing 41 and may have the plurality of spray flow paths 45 formed therein. The chamber 47 is formed to communicate with the plurality of supply flow paths 44. The gas supplied from the plurality of supply flow paths 44 may be sprayed to the wires W through the plurality of spray flow paths 45.

The chamber 47 may include the first inner space 471 and a second inner space 472 therein. For example, as illustrated in FIGS. 4 and 5, the first inner space 471 extends in the longitudinal direction of the chamber 47 and is connected to the plurality of supply flow paths 44 and the plurality of spray flow paths 45. The gas supplied from the plurality of supply flow paths 44 may pass through the first inner space 471 and then be sprayed to the wires W through the plurality of spray flow paths 45 branched downward from the first inner space 471. The first inner space 471 may have a circular cross-section, and a diameter of the cross-section may be greater than a diameter of the spray flow path 45. The first inner space 471 may be coaxial with the spray flow path 45.

The temperature sensor 48 may be inserted into the first inner space 471. The temperature sensor 48 may have a circular bar shape with a smaller diameter than the first inner space 471 and may measure the temperature of the gas supplied from the supply flow path 44 and passing through the first inner space 471. If the temperature of the gas measured by the temperature sensor 48 is lower than a predetermined temperature, the controller 90 may increase the temperature of the gas supply source 43 or increase the temperature of the auxiliary heater 49 which will be described below. Conversely, if the temperature of the gas measured by the temperature sensor 48 is higher than the predetermined temperature, the controller 90 may decrease the temperature of the gas supply source 43 or decrease the temperature of the auxiliary heater 49.

One or more second inner spaces 472 may be formed inside the chamber 47 and may have the auxiliary heater 49 inserted thereinto. For example, as illustrated in FIG. 5, a pair of second inner spaces 472 may be present at both sides of the first inner space 471. The auxiliary heater 49 inserted into each second inner space 472 may heat the chamber 47 to maintain the temperature of the gas, which is lowered due to the gas passing through the supply flow path 44, at a temperature higher than or equal to a predetermined temperature. The auxiliary heater 49 may heat the chamber 47 so that the temperature of the chamber 47 is maintained below the temperature of the gas discharged from the plurality of supply flow paths 44. The auxiliary heater 49 may heat the chamber 47 so that the temperature of the gas sprayed from the spray flow path 45 may be different from the temperature of the gas supplied from the gas supply source 43. For example, the auxiliary heater 49 may heat the chamber 47 so that the temperature of the gas sprayed from the spray flow path 45 is maintained at a temperature lower than the temperature of the gas supplied from the gas supply source 43, e.g., maintained at a temperature ranging from 200° C. to 300° C. The auxiliary heater 49 may heat the chamber 47 so that the temperature of the chamber 47, that is, the internal temperature of the chamber 47 measured by the temperature sensor 48, is maintained at a temperature of 300° C. or higher.

The auxiliary heater 49 may maintain the temperature of the gas sprayed from the plurality of spray flow paths 45 at a temperature higher than or equal to a predetermined temperature to stably melt the solder applied on the plurality of wires W. Also, the auxiliary heater 49 may have the same length as the chamber 47 in the second direction (for example, the Y-axis direction of FIG. 4) to stably heat the entire chamber 47. Accordingly, the chamber 47 and the plurality of spray flow paths 45 present inside the chamber 47 may be uniformly heated, and the temperature of the gas sprayed from the plurality of spray flow paths 45 may be uniformly maintained.

The chamber 47 may further include spray grooves 473. For example, as illustrated in FIGS. 5 and 6, the spray grooves 473 may be formed in a bottom surface of the chamber 47 to correspond to the spray flow paths 45 and may be equal in number to the spray flow paths 45. A plurality of spray grooves 473 may extend to be inclined toward both sides from lower ends of the plurality of spray flow paths 45, may extend in the width direction of the chamber 47, and may have a length L3 that is longer than the diameter of the spray flow path 45. Accordingly, a high-temperature gas sprayed from the spray flow path 45 may be, after coming into contact with a wire W, trapped between the spray groove 473 and the wire W instead of being dispersed in all directions and may effectively heat the wire W. For example, the spray groove 473 may be at the center of the spray flow path 45 and may be coaxial with the first inner space 471.

The spray groove 473 may include a pair of inclined surfaces on inner sides thereof, and the pair of inclined surfaces may have an angle θ relative to the horizontal line. Accordingly, a spray area of the spray flow path 45 communicating with the spray groove 473 may be increased, and a larger amount of gas may be sprayed to the wires W. The angle 0 may range from 20°to 70°. If 0 is less than 20°, the width of the spray groove 473 is excessively increased, and the effect of the spray groove 473 in maintaining and retaining the gas is reduced, and if 0 exceeds 70°, it is not possible to secure a large spray area of the spray flow path 45. For example, θ may range from 30° to 60°.

The drawings illustrate an embodiment in which the separating device 40 includes six supply flow paths 44 and a total of twelve spray flow paths 45 with two spray flow paths 45 included for each supply flow path 44. The separating device 40 may simultaneously spray hot air to twelve wires W attached to a defective solar cell NC and may simultaneously separate the twelve wires W from the defective solar cell NC. However, the number of supply flow paths 44 and the number of spray flow paths 45 may be appropriately selected according to the specifications of the string S and the string repair device 1. The separating device 40 may include three supply flow paths 44 and six spray flow paths 45. Here, the separating device 40 may separate six wires W from a defective solar cell NC first and then may separate the remaining six wires W from the defective solar cell NC.

The bonding device 50 may bond a wire W aligned by the aligning device 30 to a new good solar cell GC. After a defective solar cell NC is replaced with a good solar cell GC, a wire W extending from a good solar cell GC adjacent to one side of the new good solar cell GC is aligned by the aligning device 30. Then, the bonding device 50 bonds the wire W to an upper surface of the new good solar cell GC. Here, at least a portion of the bonding device 50 may overlap with the first printing area PA row closest to an end of the new good solar cell GC (for example, a left end thereof in FIG. 2J). In addition, a wire W extending from the new good solar cell GC is aligned by the aligning device 30 on an upper surface of another good solar cell GC. Then, the bonding device 50 bonds the wire W to the upper surface of the good solar cell GC. Here, at least a portion of the bonding device 50 may be located to overlap with the first printing area PA row closest to an end of the other good solar cell GC (for example, a left end thereof in FIG. 2L).

The bonding device 50 may be a high-frequency fusion bonding device. The bonding device 50 may melt solder applied to the wire W of the new good solar cell GC and bond the wire W to the printing area PA.

The bonding device 50 may be equal in number to a plurality of wires W attached to a single solar cell C. The bonding devices 50 may simultaneously bond twelve wires W to the solar cell C through pressing parts 53. Alternatively, the bonding device 50 may be fewer in number than a plurality of wires W attached to a single solar cell C. The bonding devices 50 may bond six wires W to the solar cell C through six pressing parts 53, move, and then bond the remaining six wires W to the solar cell C.

The robot arm 60 is located on one side of the stage 10 and performs an inspecting operation, a cutting operation, a bonding operation, and so on. The robot arm 60 is a six-axis robot including a vision camera 61, a single cutter 63, a single bonding device 65, and the cutter 67. For example, as illustrated in FIG. 1, the vision camera 61, the single cutter 63, the single bonding device 65, and the cutter 67 may be arranged clockwise or counterclockwise, and the robot arm 60 may rotate at 90° intervals and place the components at process positions on the string S.

The vision camera 61 may, after an end of each process of string repair, inspect whether the corresponding process has been performed properly. After a process of cutting a wire W by the cutter 67, the vision camera 61 checks a cut surface of the wire W and determines whether the wire W has been cut properly. Also, the vision camera 61 checks whether the wire W has been attached properly to a solar cell C by the bonding device 50. In addition, the vision camera 61 may be used to check another process of string repair as necessary. For example, the vision camera 61 may inspect whether the string S has been mounted properly on the stage 10, whether the wire W has been separated properly by the separating device 40, or whether a defective solar cell NC has been discharged and a new good solar cell GC has been mounted.

The single cutter 63 and the cutter 67 may cut a wire W. For example, after a wire W is separated by the separating device 40, as illustrated in FIG. 2E, the cutter 67 cuts the separated wire W on an upper surface of a defective solar cell NC. The cutter 67 may be equal in number to a plurality of wires W attached to a single solar cell C. Alternatively, the cutter 67 may be fewer in number than a plurality of wires W attached to a single solar cell C. The number of blades of the cutter 67 may be four, and the cutter 67 may cut twelve wires W through three cutting operations.

Also, as illustrated in FIG. 2E, after cutting the separated wire W on the upper surface of the defective solar cell NC, the cutter 67 may move to a good solar cell GC to which the wire W of the defective solar cell NC extends. The cutter 67 may cut the wire W at one end of the good solar cell GC.

The single cutter 63 may perform an additional cutting operation when, after the cutting operation by the cutter 67 is completed, the vision camera 61 checks the cut surface of the wire W and then determines that cutting has not been performed properly. The single cutter 63 may have a blade to be able to cut a single wire W. When the vision camera 61 detects a wire W that has not been cut properly among a plurality of wires W, the single cutter 63 may move to the corresponding wire W and perform a cutting operation for each wire again.

The single bonding device 65 may perform an additional bonding operation when, after the bonding operation by the bonding device 50 is completed, the vision camera 61 checks a bonding position of a wire W and then determines that bonding has not been performed properly. The single bonding device 65 may be a high-frequency fusion bonding device that can bond a single wire W to a solar cell C. When the vision camera 61 detects a wire W that has not been bonded properly among a plurality of wires W, the single bonding device 65 may move to the corresponding wire W and perform a bonding operation for each wire again.

The transporting device 70 may transport a string S placed outside the string repair device 1 to the inside thereof or may transport a string S within the string repair device 1. The transporting device 70 may transport a string S determined to be defective by the inspecting device 3 to a stage 10 and may transport the stage 10 on which repair of the string S has been completed to the outside of the string repair device 1. Also, the transporting device 70 may transport the stage 10 on which repair of the string S has been completed back to the inspecting device 3 for the inspecting device 3 to inspect whether the string S has been repaired properly.

The magazine 80 may contain a plurality of good solar cells GC. When a stage 10 discharges a defective solar cell NC, the third moving head 29 may, while supporting the good solar cells GC loaded in the magazine 80, move along the third horizontal guide 27 to a position where the discharged defective solar cell NC was present. Also, the third moving head 29 may place the good solar cells GC supported thereby on a stage 10 at the corresponding position.

The controller 90 may be connected to other components of the string repair device 1 wirelessly or via a wire and may control these components. The controller 90 may control lifting/lowering and forward/backward movements of a stage 10. Also, the controller 90 may adjust positions of the aligning device 30, the separating device 40, and the bonding device 50 by controlling the movement guide 20 and may control an operation of each of the aligning device 30, the separating device 40, and the bonding device 50. In addition, the controller 90 may control the robot arm 60 to control operations of the vision camera 61, the single cutter 63, the single bonding device 65, and the cutter 67.

The controller 90 may use an integrated circuit structure that executes each control function through one or more microprocessors or other control devices, such as a memory, a processor, a logic circuit, or a look-up table. The controller 90 may be implemented as a module, a program, or part of a code that includes one or more executable instructions for executing a specific logic function. The controller 90 may include, or may be implemented by, a processor such as a central processing unit executing each function or microprocessor. The controller 90 may include a communication device that can transmit and receive data to and from an external device or the like. The communication device may include a digital modem, a radiofrequency (RF) modem, an antenna circuit, a Wi-Fi chip, related software and/or firmware, or a combination of one or more thereof.

Next, operations of the string repair device 1 and a string repair method will be described.

A string repair method includes placing a string S including a plurality of solar cells C including a plurality of printing areas PA and a plurality of wires W connecting the plurality of solar cells C on a stage 10, separating a plurality of wires W attached to a plurality of printing areas PA of a defective solar cell NC among the plurality of solar cells C from the defective solar cell NC, and cutting the separated plurality of wires W, wherein the plurality of printing areas PA form a plurality of rows in a longitudinal direction, and the separating of the plurality of wires W from the defective solar cell NC may include separating the plurality of wires W attached to the plurality of printing areas PA of the first row among the plurality of printing areas PA of the defective solar cell NC from the defective solar cell NC.

The separating of the plurality of wires W from the defective solar cell NC may include separating the plurality of wires W from the defective solar cell NC throughout areas ranging from one end of the defective solar cell NC to positions spaced a predetermined distance rearward from the plurality of printing areas PA of the first row.

First, when the inspecting device 3 determines that a string S is defective, the controller 90 sends a signal to the transporting device 70, and the transporting device 70 mounts the corresponding string S on a stage 10 (see FIG. 2A). The transporting device 70 transports the string S so that a defective solar cell NC included in the string S is placed on a central portion of the stage 10 and the remaining good solar cells GC are placed on other portions of the stage 10.

Next, the controller 90 sends a lifting/lowering signal to the stage 10 and moves the separating device 40 to the defective solar cell NC (see FIG. 2C). Based on the stage 10 on which the defective solar cell NC is mounted, the stage 10 located at a front moves upward and the stage 10 located at a rear moves downward, thereby forming step differences between the good solar cells GC and the defective solar cell NC. Then, while located at a separation position Pd, that is, located to correspond to the first printing area PA row of the defective solar cell NC, the separating device 40 separates a plurality of wires W from the defective solar cell NC.

The separating device 40 may, at positions spaced a predetermined distance rearward from the first printing area PA row of the defective solar cell NC, separate the plurality of wires W from the defective solar cell NC.

The separating device 40 may separate the plurality of wires W from the defective solar cell NC by heating the plurality of wires W. When the separating device 40 is located at the separation position Pd, the control valve 46 is open, and a heated gas is supplied from the gas supply source 43 to the supply flow path 44. The gas may be heated again through the chamber 47 and then may be branched and sprayed onto each wire W through the spray flow paths 45. The separating device 40 may spray hot air having a temperature higher than or equal to a melting point of solder applied on the plurality of wires W to the plurality of wires W.

Then, the controller 90 may send the lifting/lowering signal again to the stages 10, and the stage 10 located at the front may further move upward and pull the wire W upward. Also, the stage 10 located at the rear may further move downward and pull the wire W downward. For example, during an additional lifting/lowering operation of the stages 10, the separating device 40 may deviate from the wire W or may continue to heat the wire W.

Then, the controller 90 sends a cutting signal to the robot arm 60, and the robot arm 60 moves to a position where the wire W has been separated and cuts the wire W with the cutter 67. As illustrated in FIG. 2E, the cutter 67 may cut the wire W so that the wire W extends rearward past the first printing area PA row of the defective solar cell NC. Then, as illustrated in FIG. 2E, the cutter 67 cuts the wire W extending from the defective solar cell NC at a front end of the good solar cell GC located at the rear of the defective solar cell NC. The cutter 67 may cut the wires W in reverse order, or a plurality of cutters 67 may simultaneously cut each wire W.

Whether cutting has been performed properly by the cutter 67 may be checked through the vision camera 61. For example, after the cutting operation by the cutter 67, the controller 90 sends an inspection signal to the robot arm 60, and the robot arm 60 checks a cut surface of the wire W using the vision camera 61. If the wire W has been cut properly, the controller 90 performs a subsequent process. If the wire W has not been cut properly, the robot arm 60 uses the single cutter 63 to individually cut the wire W that has not been cut properly.

Then, the controller 90 sends a discharge signal to the stage 10, and the stage 10 supporting the defective solar cell NC rotates and discharges the defective solar cell NC (see FIG. 2G). Next, the controller 90 sends a lifting/lowering signal to the stage 10 and sends a pickup signal to the magazine 80 or the third moving head 29. The stages 10 located at both sides of the unoccupied stage 10 move downward and upward and return to their original positions, and the third moving head 29 supports a new good solar cell GC and mounts the new good solar cell GC on the unoccupied stage 10 (see FIG. 2H). In this state, the plurality of wires W attached to the good solar cell GC located at the front may be located on the new good solar cell GC, and the plurality of wires attached to the new good solar cell GC may be located on the good solar cell GC located at the rear.

Next, the controller 90 sends an alignment signal to the aligning device 30. The aligning device 30 moves to a position corresponding to the first printing area PA row of the defective solar cell NC, that is, the first position P1, and then primarily moves downward (see FIG. 2I). Accordingly, the wire W extending from the good solar cell GC located at the front and stretching to an upper portion of the new good solar cell GC is aligned downward. Then, the aligning device 30 moves upward again, moves rearward, moves to the second position P2, and then secondarily moves downward. The aligning device 30 that has secondarily moved downward gathers the wire W in the width direction while pressing the wire W downward and places the wire W extending from the good solar cell GC located at the front in the first printing area PA row. Then, the bonding device 50 receives a signal from the controller 90, moves to the first position P1, and then moves downward. The bonding device 50 bonds two wires W located in a single first printing area PA row, that is, the wire W extending from the good solar cell GC located at the front and the wire W attached to the new good solar cell GC, in the first printing area PA row (see FIG. 2J).

Then, the aligning device 30 moves rearward again, moves to a position corresponding to the first printing area PA row of the good solar cell GC located at the rear, that is, the third position P3, and then primarily moves downward (see FIG. 2K). Accordingly, the wire W extending from the new good solar cell GC and stretching to an upper portion of the good solar cell GC located at the rear is aligned downward. Then, the aligning device 30 moves upward again, moves rearward, moves to the fourth position P4, and then secondarily moves downward. The aligning device 30 that has secondarily moved downward gathers the wire W in the width direction while pressing the wire W downward and places the wire W extending from the new good solar cell GC in the first printing area PA row. Then, the bonding device 50 receives a signal from the controller 90, moves to the third position P3, and then moves downward. The bonding device 50 bonds two wires W located in a single first printing area PA row, that is, the wire W extending from the new good solar cell GC and the wire W attached to the good solar cell GC located at the rear, in the first printing area PA row (see FIG. 2L).

Whether bonding has been performed properly may be checked using the vision camera 61. For example, after the bonding operation by the bonding device 50, the controller 90 sends an inspection signal to the robot arm 60, and the robot arm 60 checks states of the bonded wires W in the printing areas PA using the vision camera 61. If the wires W are bonded properly in the printing areas PA, the controller 90 performs a subsequent process. If the wires W are not bonded properly in the printing areas PA, the robot arm 60 uses the single bonding device 65 to individually bond the wire W that has not been bonded properly.

Although the present invention has been described above with reference to the embodiments illustrated in the drawings, the description is merely illustrative. Those of ordinary skill in the art may fully understand that various modifications and other equivalent embodiments are possible from the embodiments. Therefore, the true technical protection scope of the present invention should be defined based on the appended claims.

### INDUSTRIAL APPLICABILITY

Embodiments of the present disclosure may be used in industries relating to a string repair device and a string repair method.

1. A string repair device comprising:
a stage supporting a string including a plurality of solar cells including a plurality of printing areas and a plurality of wires connecting the plurality of solar cells; and
a separating device configured to separate a plurality of wires attached to a plurality of printing areas of a defective solar cell among the plurality of solar cells from the defective solar cell,
wherein the plurality of printing areas form a plurality of rows in a longitudinal direction,
the separating device is present in an area that corresponds to the plurality of wires present in a plurality of printing areas of a first row among the plurality of printing areas of the defective solar cell,
the separating device provides thermal energy of a first temperature or higher to the corresponding area, and
the first temperature is a melting point of solder applied on the plurality of wires.

2. The string repair device of claim 1, wherein the separating device separates the plurality of wires attached to the plurality of printing areas of the first row among the plurality of printing areas of the defective solar cell from the defective solar cell.

3. The string repair device of claim 1, wherein the separating device separates the plurality of wires from the defective solar cell throughout positions spaced a predetermined distance rearward from the plurality of printing areas of the first row.

4. The string repair device of claim 1, wherein the separating device includes:
a housing;
a plurality of supply flow paths present inside the housing and connected to a gas supply source;
a plurality of spray flow paths branched from lower ends of the plurality of supply flow paths; and
a chamber present below the housing and in which the plurality of spray flow paths, a temperature sensor, and one or more auxiliary heaters are present,
wherein the separating device sprays a high-temperature gas on the defective solar cell to separate the plurality of wires in the plurality of printing areas of the first row.

5. The string repair device of claim 4, wherein the one or more auxiliary heaters heat the chamber and maintain a temperature of the chamber below a temperature of a gas discharged from the plurality of supply flow paths.

6. The string repair device of claim 4, wherein the chamber includes:
a first inner space communicating with each of the plurality of supply flow paths and the plurality of spray flow paths; and
a pair of second inner spaces present on both sides of the first inner space,
wherein the temperature sensor is present in the first inner space, and
the one or more auxiliary heaters are present in the pair of second inner spaces.

7. The string repair device of claim 4, wherein the chamber includes, in a bottom surface thereof, a plurality of spray grooves having a length greater than a diameter of the plurality of spray flow paths and extending to be inclined to both sides from lower ends of the plurality of spray flow paths.

8. A string repair method comprising:
placing a string including a plurality of solar cells including a plurality of printing areas and a plurality of wires connecting the plurality of solar cells on a stage;
separating a plurality of wires attached to a plurality of printing areas of a defective solar cell among the plurality of solar cells from the defective solar cell; and
cutting the separated plurality of wires,
wherein the plurality of printing areas form a plurality of rows in a longitudinal direction,
the separating of the plurality of wires from the defective solar cell includes providing thermal energy of a first temperature or higher to an area that corresponds to the plurality of wires present in a plurality of printing areas of a first row among the plurality of printing areas of the defective solar cell, and
the first temperature is a melting point of solder applied on the plurality of wires.

9. The string repair method of claim 8, wherein the separating includes separating the plurality of wires attached to the plurality of printing areas of the first row among the plurality of printing areas of the defective solar cell from the defective solar cell.

10. The string repair method of claim 8, wherein the separating of the plurality of wires from the defective solar cell includes separating the plurality of wires from the defective solar cell throughout positions spaced a predetermined distance rearward from the plurality of printing areas of the first row.
